(19) United States
(12) Patent Application Publication
(10) Pub. No.: US 2025/0311248 A1
(43) Pub. Date: Oct. 2, 2025

(54) CAPACITOR AND METHOD FOR FABRICATING THE SAME

(71) Applicant: TEXAS INSTRUMENTS INCORPORATED, DALLAS, TX (US)

(72) Inventor: Enis TUNCER, DALLAS, TX (US)

(21) Appl. No.: 18/620,131

(22) Filed: Mar. 28, 2024

(51) Int. Cl. H01L 23/00

(52) U.S. Cl. CPC H10D 1/043; H10D 1/714; H10D 1/716; H01L 24/48; H01L 2224/48091; H01L 2224/48105; H01L 2224/48245

(57) ABSTRACT

In a described example, an apparatus can include a multi-layer substrate and a capacitor device. The multi-layer substrate has a first surface and a second surface. The capacitor device is on the second surface of the multi-layer substrate. The capacitor device can include a conductive substrate layer, a dielectric layer, a first capacitor terminal, and a second capacitor terminal. The conductive substrate layer can include a first set of fingers and a second set of fingers. The first set of fingers is interdigitated with the second set of fingers. The dielectric layer is between the first and second set of fingers. The first capacitor terminal is coupled to the first set of fingers. The second capacitor terminal is coupled to the second set of fingers.

### TECHNICAL FIELD

This description relates generally to electrical devices, and more particularly to a capacitor and a method for fabricating a capacitor.

### BACKGROUND

A capacitor is a device that stores electrical energy by accumulating electric charges on two or more closely spaced conductive surfaces that are insulated from each other by a dielectric. The physical form and construction of capacitors can vary widely, such as depending on the use environment, mounting method, and capacitance value for a given application.

### SUMMARY

In a described example, an apparatus can include a multi-layer substrate and a capacitor device. The multi-layer substrate has a first surface and a second surface. The capacitor device is disposed on the second surface of the multi-layer substrate. The capacitor device can include a substrate layer, a dielectric layer, a first capacitor terminal, and a second capacitor terminal. The substrate layer can include a first set of fingers and a second set of fingers. The first set of fingers is interdigitated with the second set of fingers. The dielectric layer is disposed between the first and second set of fingers. The first capacitor terminal is coupled to the first set of fingers. The second capacitor terminal is coupled to the second set of fingers.

In a described example, a method can include forming a multi-layer substrate on a first surface of a substrate layer, removing a portion of the substrate layer from a second surface thereof to form a first set of fingers and a second set of fingers and to expose a first surface of the multi-layer substrate through interstitial spaces between the first and second sets of fingers, the first and second sets of fingers are electrically isolated from each other by the interstitial space and the first and second surfaces of the multi-layer substrate are opposite each other, and forming a dielectric layer in interstitial spaces between the first and second sets of fingers to capacitively couple the first and second sets of fingers.

In a described example, a packaged integrated circuit (IC) can include a multi-layer substrate, a capacitor, active circuitry, and molding compound. The multi-layer substrate has first and second opposing surfaces. The capacitor is disposed on the second surface of the multi-layer substrate. The active circuitry is disposed in the multi-layer substrate or in at least one other layer on the first surface of the multi-layer substrate. The molding compound encapsulates the active circuitry, the multi-layer substrate, and the capacitor. The capacitor can include first and second sets of interdigitated and electrically conductive fingers extending from a first surface of a substrate layer to terminate at a second surface of the substrate layer, the first and second sets of fingers extend orthogonally to the second surface of the multi-layer substrate to define interstitial spaces between adjacent pairs of fingers of the first and second sets of fingers, and the second surface of the multi-layer substrate is exposed in the interstitial spaces between the adjacent pairs of fingers and a dielectric layer disposed in the interstitial spaces between the adjacent pairs of fingers.

In a described example, a packaged integrated circuit (IC) can include a multi-layer substrate, a capacitor, and a molding compound. The multi-layer substrate has first and second opposing surfaces. The capacitor is disposed on the second surface of the multi-layer substrate. The molding compound encapsulates the substrate layer, the multi-layer substrate, and the capacitor. The capacitor can include first and second sets of interdigitated and electrically conductive fingers extending from a first surface of a substrate layer to terminate at a second surface of the substrate layer, the first and second sets of fingers extend orthogonally to the second surface of the multi-layer substrate to define interstitial spaces between adjacent pairs of fingers of the first and second sets of fingers, and the second surface of the multi-layer substrate is exposed in the interstitial spaces between the adjacent pairs of fingers and a dielectric layer disposed in the interstitial spaces between the adjacent pairs of fingers.

### BRIEF DESCRIPTION OF THE DRAWINGS

FIG. 1 is a flow diagram of an example method for manufacturing a capacitor in a substrate.

FIG. 2 is a diagram of an example process flow for manufacturing a capacitor in a substrate.

FIGS. 3A-3B are diagrams of examples of process flows for manufacturing a capacitor in a substrate.

FIG. 4 is a diagram of an example process flow for manufacturing a capacitor in a substrate.

FIG. 5 is a diagram of an example process flow for manufacturing a capacitor in a substrate.

FIGS. 6A-6B are diagrams of examples of process flows for manufacturing a capacitor in a substrate.

FIGS. 7A-7B are diagrams of examples of process flows for manufacturing a capacitor in a substrate.

FIG. 8 is a cross-sectional diagram of an example packaged integrated circuit (IC) including a capacitor in a substrate.

FIG. 9 is a cross-sectional diagram of part of an example capacitor.

FIG. 10 is a cross-sectional diagram of another example capacitor.

FIG. 11 is an exploded, perspective view of an example capacitor in a substrate.

FIG. 12 is a sectional view of a portion of the example capacitor of FIG. 11 taken along line 12-12.

### DETAILED DESCRIPTION

This description relates to an on-chip capacitor device, such as a capacitor fabricated in a substrate of a semiconductor material (e.g., on the backside of a semiconductor wafer). For example, active circuitry is formed on the top side of a conductive substrate layer. From the bottom side or backside of the conductive substrate layer, photoresist is applied and patterned, and first and second sets of fingers are formed (e.g., via deep trench etching). The first and second sets of fingers are interdigitated with one another and interstitial gaps are provided between adjacent fingers of the first and second set of fingers. The first and second set of fingers are configured as conductors (e.g., plates) for the capacitor. A first capacitor terminal is coupled to the first set of fingers and a second capacitor terminal is coupled to the second set of fingers. The first and second capacitor terminals enable electrical connectivity to the capacitor. A dielectric material is provided in the interstitial gaps between the first and second sets of fingers. The dielectric material can act to increase the charge capacity of the capacitor while providing mechanical support for the semiconductor device.

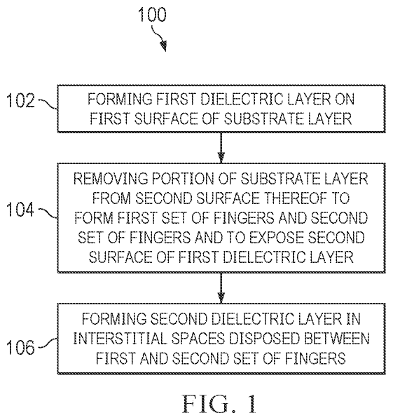

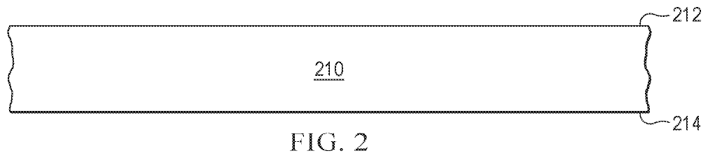

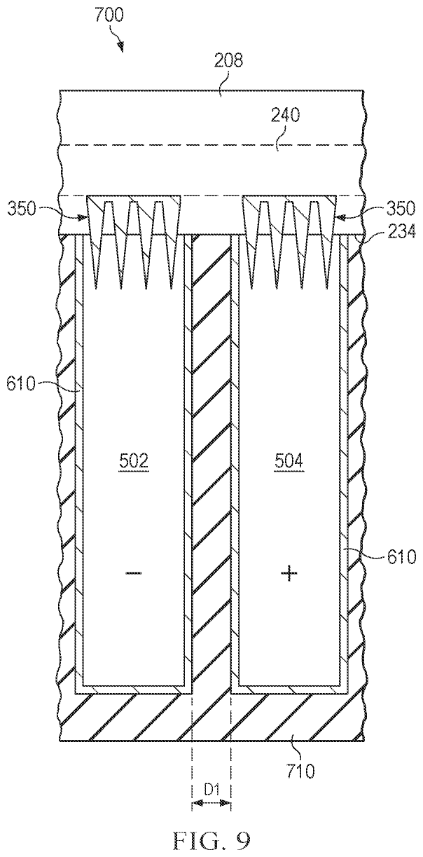

FIG. 1 is a flow diagram of an example fabrication process or method 100 for manufacturing a capacitor (also referred to as a capacitor device or on-chip capacitor) in a substrate, which can be encapsulated to provide a packaged integrated circuit (IC) including the capacitor in the substrate. FIG. 1 is described herein with respect to the examples of process flows for manufacturing the capacitor in the substrate of FIGS. 2-8 and the corresponding capacitor device shown in FIGS. 9-12.

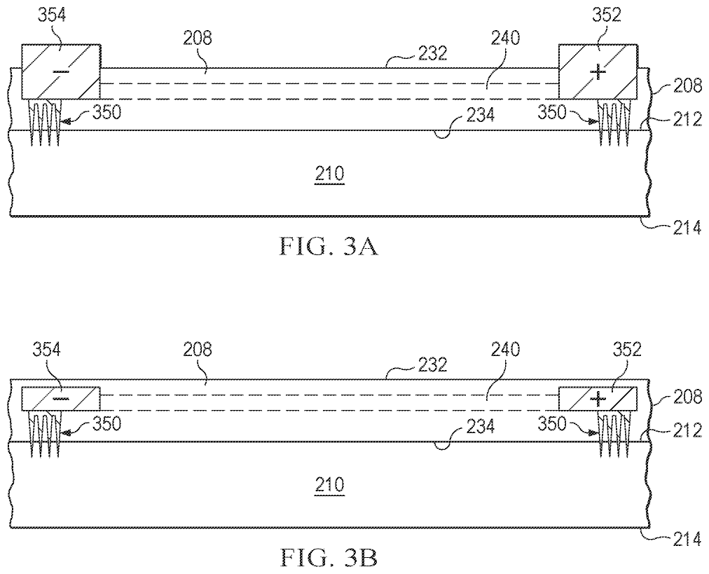

At 102, the method 100 can include forming a multi-layer substrate on a first surface of a conductive substrate layer 210. For example, FIGS. 3A-3B show a multi-layer substrate 208 on a first surface 212 of a conductive substrate layer 210. The multi-layer substrate 208 can include multiple layers of materials, such as one or more layers of dielectric material, one or more layers of metal, etc. The conductive substrate layer 210 also has a second surface 214 opposing the first surface 212. The multi-layer substrate 208 has a first surface 232 and a second surface 234 opposing the first surface 232. The multi-layer substrate 208 can be formed of silicon oxide (SiO2) and the conductive substrate layer 210 can be formed of silicon (Si). The multi-layer substrate 208 can include a circuit 240 (e.g., active circuit or active circuitry). According to one example, the circuit 240 can be embedded within the multi-layer substrate 208. According to another example, the circuit 240 can be optional and omitted from the device.

With reference to FIGS. 3A-3B, the method 100 can include forming vias 350 including a first capacitor terminal 352 and a second capacitor terminal 354. In one example, the vias 350 can extend from the first capacitor terminal 352 and the second capacitor terminal 354 to the conductive substrate layer 210. It will be appreciated that FIGS. 3A-3B are not necessarily drawn to scale, and thus, the vias 350 can extend from the first capacitor terminal 352 and the second capacitor terminal 354 to near the first surface 212 or to near the second surface 214 of the conductive substrate layer 210. The circuit 240 can be coupled to the first capacitor terminal 352 and the second capacitor terminal 354 of the capacitor, and thus, the circuit 240 is electrically coupled to the capacitor (e.g., after the capacitor is fabricated). FIG. 3A illustrates an example where the vias 350 extend from the first and second capacitor terminals 352 and 354 at the first surface 232, through the multi-layer substrate 208 and into the conductive substrate layer 210. In this example, the capacitor can be connected to components external to the semiconductor device via the first and second capacitor terminals 352, 354. FIG. 3B illustrates an example where the first and second capacitor terminals 352, 354 are partially embedded within the multi-layer substrate 208. In other examples, such as in FIG. 3A, the capacitor terminals 352, 354 can be formed on the first surface 232 of the multi-layer substrate 208. In FIG. 3B, the capacitor is internal to the semiconductor device and electrically coupled to the circuit 240 using the first and second capacitor terminals 352, 354.

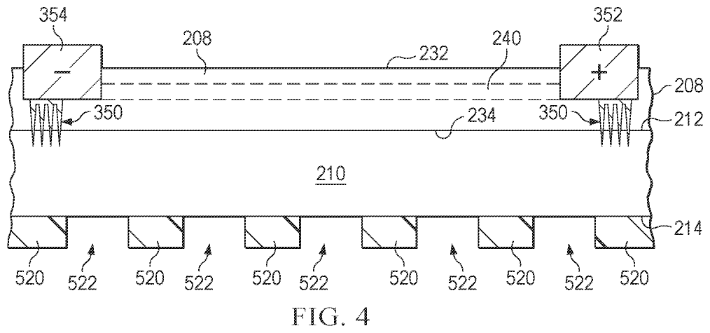

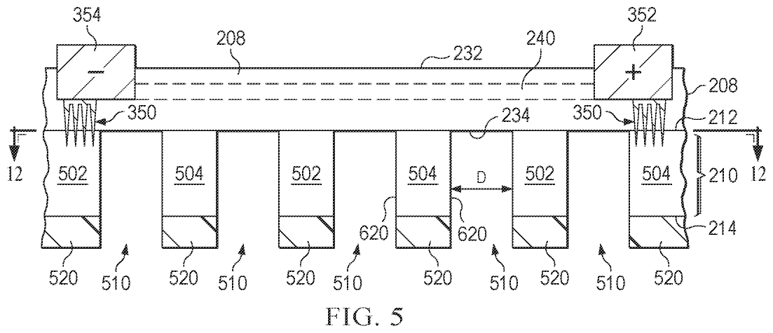

At 104, the method 100 can also include removing a portion of the conductive substrate layer from the second surface 214 thereof to form a number of interdigitated conductive fingers, such as including a first set of fingers and a second set of fingers. For example, as shown in FIGS. 4-5, this can include exposing the second surface 234 of the multi-layer substrate 208 to create a plurality of interstitial spaces 510 between adjacent pairs of fingers. In this way, the first set of fingers 502 is interdigitated with the second set of fingers 504. The first capacitor terminal 352 is coupled to the first set of fingers 502 and the second capacitor terminal 354 is coupled to the second set of fingers 504. As discussed, the first and second set of fingers 502, 504 are formed of an electrically conductive material, such as silicon (Si). In the illustrated example, there are N=6 conductive fingers, but other examples can have more or fewer fingers, the number N being a design parameter that can determine the operational properties of the capacitor, such as a capacitance value. The first and second set of fingers 502, 504 can be separated from each other by an interdigitation gap distance D and be fabricated to have a dielectric constant ε_{rFINGER}.

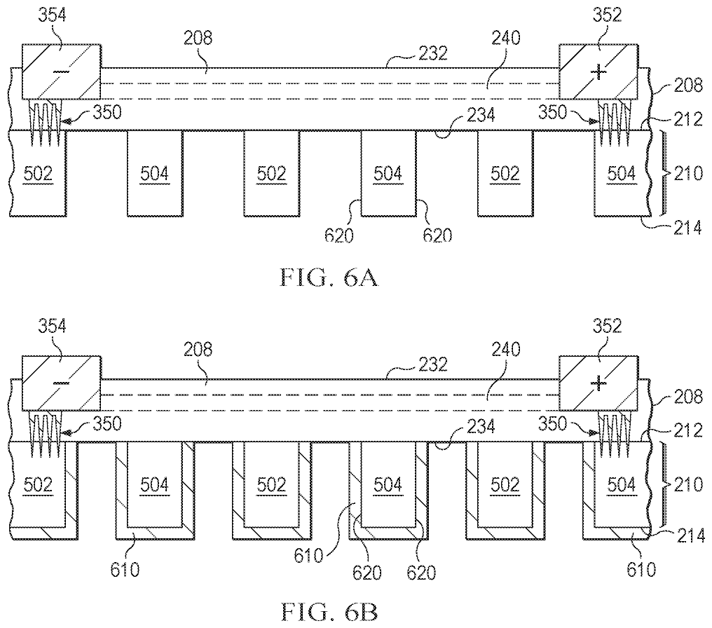

As shown in FIG. 4, removing the portion of the conductive substrate layer 210 from the second surface 214 thereof can include forming a mask layer 520 (e.g., photoresist) on the second surface 214 of the conductive substrate layer 210, and patterning the mask layer 520. The conductive substrate layer 210, once patterned by the mask layer 520 and etched, can include a first and second set of fingers 502, 504 interdigitated with one another. A portion of the mask layer 520 can be removed to form respective openings 522 in the mask layer. The openings 522 in the mask can then be etched, as seen in FIG. 5, to remove the substrate layer therein, such as by performing deep trench etching of the conductive substrate layer 210 to remove 104 the portion of the conductive substrate layer 210, thereby forming the first and second set of fingers 502, 504 to be interdigitated with one another. In this way, the first and second set of fingers 502, 504 extend from the second surface 234 of the multi-layer substrate 208 and terminate at the second surface 214 parallel to line 12-12 in FIG. 5. Thereafter, the mask layer 520 is removed, as seen in FIGS. 6A-6B. The mask layer 520 can be formed of a photoresist material, for example.

In some examples, a metal layer 610 is formed in the interstitial spaces 510 between the first and second set of fingers 502, 504, as seen in FIG. 6B. The metal layer 610 can be formed on the respective fingers, such as over sidewall surfaces 620 that define the interstitial spaces 510; however, the bottom, second surface 234 of the multi-layer substrate 208 remains free of the metal layer. The sidewall surfaces 620 of the first and second set of fingers 502, 504 are orthogonal to the second surface of the multi-layer substrate 208. The metal layer 610 can be formed of wafer level metals such as Al, W, Pt, Cu, Ti, NiPt, etc.

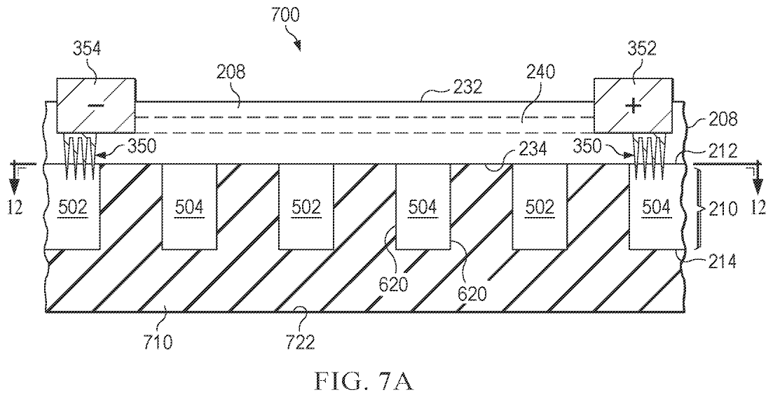

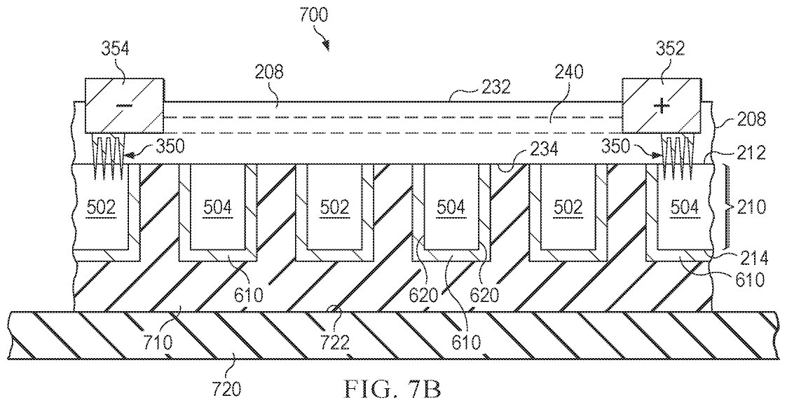

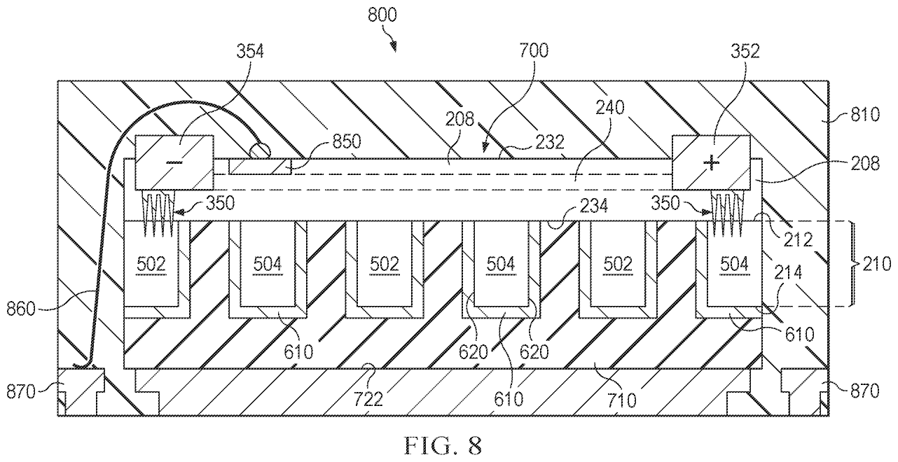

At 106, the method 100 also includes forming a dielectric layer over and between the first and second sets of fingers. For example, as shown in FIGS. 7A-7B, a dielectric layer 710 is disposed in the interstitial spaces 510 between the first and second set of fingers 502, 504 (e.g., between adjacent pairs of fingers) and over the distal ends of the respective fingers. The dielectric layer 710 extends from the second surface 234 of the multi-layer substrate 208 to cover the first and second set of fingers 502, 504. FIG. 7A illustrates an example where no metal layer is formed. FIG. 7B illustrates an example where the dielectric layer 710 is formed on the metal layer 610, such as shown in FIG. 6B. The metal layer 610 provides the benefit of additional conductivity. For example, the metal layer 610 improves high frequency performance and capacitance because the metal layer 610 inhibits (or prevents) an electric field from penetrating into the silicon substrate. Additionally, a backside layer 720 can be applied to a surface 722 of the dielectric layer 710, such as an insulating layer (e.g., an oxide) to insulate the capacitor 700 from physical damage or electrical interference.

As a further example, the dielectric layer 710 can be formed of a tantalum oxide slurry (e.g., tantalum oxide+solid electrode (MnO₂)) according to one example or of a high-permittivity dielectric or high-κ dielectric (e.g., greater than a high-permittivity dielectric threshold, such as fifty) according to another example. The high-permittivity dielectric can have a relative permittivity of one hundred, for example. According to another example, the high-permittivity dielectric can be selected from a range of values between fifty and ten thousand. According to yet another example, the high-permittivity dielectric can have a value greater than two hundred and fifty thousand. Examples of high-κ dielectric materials include, but are not limited to titanium dioxide, strontium titanate, barium strontium titanate, barium titanate, and calcium copper titanate. Additionally, the dielectric layer 710 is formed of a high-dielectric strength trench filling material to provide mechanical support for the capacitor 700.

In this way, the capacitor 700 (e.g., a capacitor device) is formed on the second surface 234 of the multi-layer substrate 208 and is embedded during packaging, thereby eliminating the need for discrete capacitors separate from the semiconductor device, while enabling higher power densities due to the integration of the capacitor 700 directly into the semiconductor device and improving the mechanical stability of the deep trench etched structure. For example, the circuit 240 can include a power stage and the capacitor formed can be coupled to an output of the power stage through the terminals, thereby allowing higher power densities due to the integration of the power capacitor in the capacitor 700. The capacitor can include the conductive substrate layer 210, the dielectric layer 710, and the first and second capacitor terminals 352, 354. In this way, the circuit 240 is non-coplanar with the capacitor 700.

With reference to FIG. 8, a packaged integrated circuit (IC) 800 can include the capacitor 700 in the substrate and a molding compound 810 encapsulating the circuit 240 (e.g., active circuitry), the multi-layer substrate 208, and the capacitor 700. A bond pad 850 on the circuit 240 is coupled to a wire bond 860 and to a leadframe terminal 870. It will be appreciated that FIG. 8 (and other FIGS.) is not necessarily drawn to scale. For example, the first and second set of fingers 502, 504 can include many more fingers for each set.

It will be appreciated that any silicon technology can employ the capacitor in the substrate approach disclosed herein. In this regard, FIG. 9 is a partial cross-sectional diagram of an example ceramic-based capacitor in a substrate. For example, a high-κ dielectric material having relative permittivity greater than approximately fifty is disposed between a first finger of the first set of fingers 502 and a second finger of the second set of fingers 504. In FIG. 9, the first and second set of fingers 502, 504 are separated by a distance D1. Vias 350 enable the circuit 240 to be coupled to the first and second set of fingers 502, 504 of the capacitor 700.

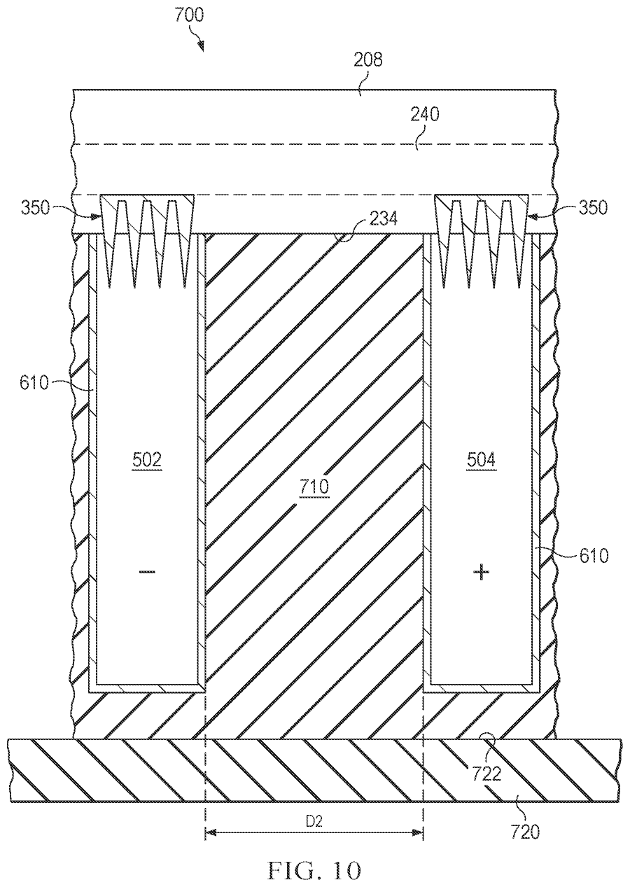

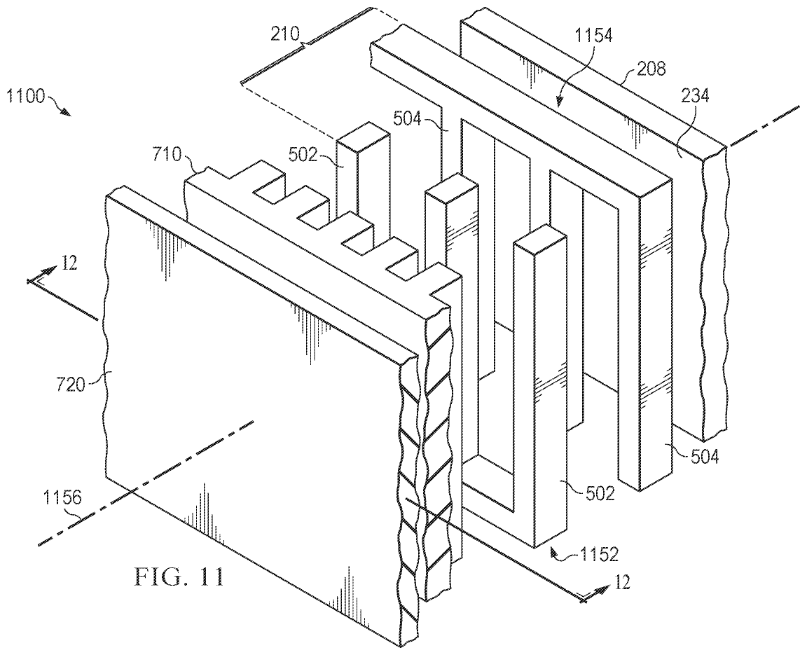

FIG. 10 is a partial cross-sectional diagram of an example tantalum-based capacitor in a substrate. For example, a tantalum oxide slurry is disposed between a first finger of the first set of fingers 502 and a second finger of the second set of fingers 504. The first and second set of fingers 502, 504 are separated by a distance D2. Vias 350 enable the circuit 240 to be coupled to the first and second set of fingers 502, 504 of the capacitor 700. According to one example, the backside layer 720 is disposed on the surface 722 of the dielectric layer 710.

In this regard, differences between the example ceramic-based capacitor and the example tantalum-based capacitor can include a difference in a distance (e.g., D1 of FIG. 9, D2 of FIG. 10) between the first and second set of fingers 502, 504 and a difference in material for the dielectric layer 710 (e.g., a high-κ dielectric material or a tantalum oxide slurry).

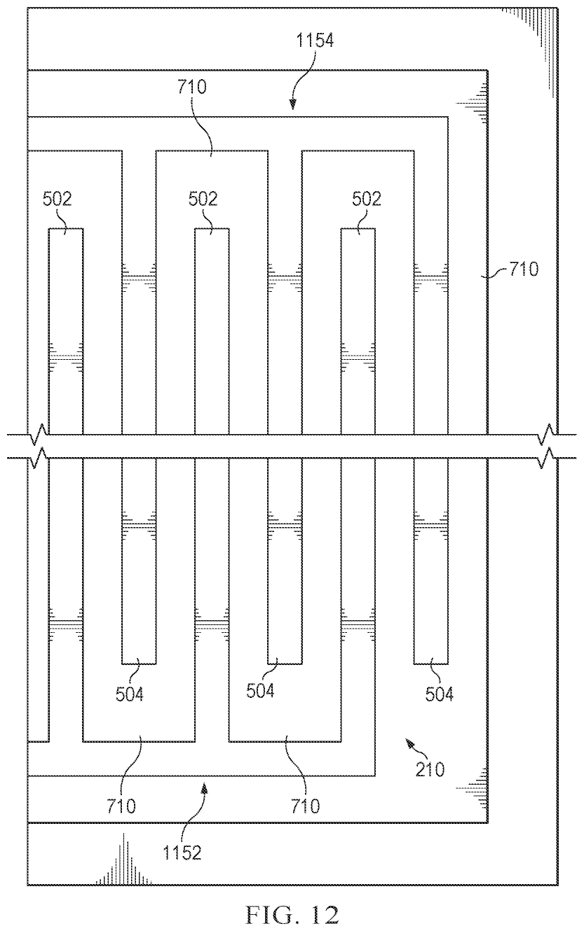

FIG. 11 is an exploded, perspective view of an example capacitor device 1100, can be formed according to the method 100 of FIG. 1. The capacitor device 1100 is an example of the capacitor 700 of FIGS. 7A and 7B. Accordingly, the description of FIG. 11 also refers to aspects of FIGS. 7A and 7B. The capacitor device 1100 thus includes the multi-layer substrate 208, the conductive substrate layer 210 is deep trench etched to form the first and second set of fingers 502, 504, and the dielectric layer 710. The first and second set of fingers 502, 504 are formed from the conductive substrate layer 210 by patterning a mask layer 520 (see, e.g., the interdigitated pattern shown in FIG. 12). For example, the first and second set of fingers 502, 504 are interdigitated with one another and spaced apart from one another by a distance, such as D1 or D2 of FIGS. 9-10. Additionally, the first set of fingers 502 extend from a first end portion 1152 on a first side towards a second, opposite side. Conversely, the second set of fingers 504 extend from a second end portion 1154 of the second side towards the first side. For example, the first and second end portions 1152 and 1154 can be arranged and configured as parallel sheets of the substrate material 210 spaced apart from each other and at opposite sides of the capacitor device 1100. The end portion 1152 and fingers 502 can form a first plate structure of the capacitor device 1100 and the end portion 1154 and fingers 504 can form a second plate structure of the capacitor device 1100. The fingers of the first and second sets of fingers 502, 504 also extend parallel to and interdigitated with respect to one another. Further, the first and second set of fingers 502, 504 extend from the second surface 234 of the multi-layer substrate 208 and terminate at an edge along a backside layer 720 in a direction parallel to an axis 1156. As shown, the axis 1156 extends through the capacitor device 1100 in a direction orthogonal to the surface of the backside layer 720. In this way, the first and second set of fingers 502, 504 and the dielectric layer 710 are configured to act as a capacitor device 1100. Additionally, the backside layer 720 can provide insulation and act as a protective layer.

FIG. 12 is a sectional view of the example capacitor 1100, taken along line 12-12 in FIGS. 7A and 11. As seen in FIG. 12, the first and second sets of interdigitated and electrically conductive fingers 502, 504 extend orthogonal to the second surface 234 of the multi-layer substrate 208 from the first surface 212 of the electrically conductive substrate layer 210 to terminate at the second surface 214 of the conductive substrate layer 210 and define the interstitial spaces 510 between adjacent pairs of fingers of the first and second sets of fingers 502, 504. The dielectric layer 710 is formed over and between the first and second sets of fingers 502, 504.

In this description, the term “couple” can cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

In this description, a device that is “configured to” perform a task or function can be configured (e.g., programmed and/or hardwired) at a time of manufacturing by a manufacturer to perform the function and/or can be configurable (or reconfigurable) by a user after manufacturing to perform the function and/or other additional or alternative functions. The configuring can be through firmware and/or software programming of the device, through a construction and/or layout of hardware components and interconnections of the device, or a combination thereof. Furthermore, a circuit or device that is described herein as including certain components can instead be configured to couple to those components to form the described circuitry or device. For example, a structure described herein as including one or more semiconductor elements (such as transistors), one or more passive elements (such as resistors, capacitors, and/or inductors), and/or one or more sources (such as voltage and/or current sources) can instead include only the semiconductor elements within a single physical device (e.g., a semiconductor die and/or integrated circuit (IC) package) and can be configured to couple to at least some of the passive elements and/or the sources to form the described structure, either at a time of manufacture or after a time of manufacture, such as by an end-user and/or a third-party.

The phrase “based on” means “based at least in part on”. Therefore, if X is based on Y, X can be a function of Y and any number of other factors.

Modifications are possible in the described embodiments, and other embodiments are possible, within the scope of the claims.

What is claimed is:

1. An apparatus, comprising:
a multi-layer substrate having a first surface and a second surface; and
a capacitor device on the second surface of the multi-layer substrate, the capacitor device comprising:
a substrate layer including a first set of fingers and a second set of fingers, the first set of fingers interdigitated with the second set of fingers;
a dielectric layer between the first and second set of fingers;
a first capacitor terminal coupled to the first set of fingers; and
a second capacitor terminal coupled to the second set of fingers.

2. The apparatus of claim 1, wherein a circuit is embedded within or on the multi-layer substrate, the circuit being coupled to the first capacitor terminal and the second capacitor terminal of the capacitor device.

3. The apparatus of claim 1, wherein the substrate layer comprises silicon and the apparatus further comprises a metal layer interposed between the dielectric layer along at least some of the fingers of the first and second sets of fingers.

4. The apparatus of claim 3, wherein the metal layer comprises wafer-level metals.

5. The apparatus of claim 1, further comprising:
a first via extending between at least one finger of the first set of fingers in the substrate layer and first capacitor terminal; and
a second via extending between at least one finger of the second set of fingers in the substrate layer and the second capacitor terminal.

6. The apparatus of claim 5, wherein conductive material of each of the first and second capacitor terminals extends through the first surface of the multi-layer substrate to define respective first and second conductive pads.

7. The apparatus of claim 5, wherein conductive material of each of the first and second capacitor terminals extends through the first and second vias from the substrate layer to terminate respective locations embedded within the multi-layer substrate between the first and second surfaces thereof.

8. The apparatus of claim 1, wherein the multi-layer substrate comprises silicon oxide (SiO2) and wherein the substrate layer comprises silicon (Si).

9. The apparatus of claim 1, wherein the dielectric layer comprises tantalum oxide.

10. The apparatus of claim 1, wherein the dielectric layer comprises a dielectric material having relative permittivity greater than approximately fifty.

11. The apparatus of claim 1, wherein the first and second set of fingers extend from the second surface of the multi-layer substrate.

12. The apparatus of claim 1, wherein sidewall surfaces of the first and second set of fingers are orthogonal to the second surface of the multi-layer substrate.

13. The apparatus of claim 1, wherein the dielectric layer extends from the second surface of the multi-layer substrate to cover the first and second set of fingers.

14. A method, comprising:
forming a multi-layer substrate on a first surface of a substrate layer;
removing a portion of the substrate layer from a second surface thereof to form a first set of fingers and a second set of fingers and to expose a first surface of the multi-layer substrate through interstitial spaces between the first and second sets of fingers, wherein the first and second sets of fingers are electrically isolated from each other by the interstitial space and the first and second surfaces of the multi-layer substrate are opposite each other; and
forming a dielectric layer in interstitial spaces between the first and second sets of fingers to capacitively couple the first and second sets of fingers.

15. The method of claim 14, wherein removing the portion of the substrate layer from the second surface thereof includes:
forming a mask layer on the second surface of the substrate layer;
forming a pattern in the mask layer to expose the second surface of the substrate layer through the mask layer; and
etching the exposed second surface of the substrate layer to remove the portion of the substrate layer and form the interstitial spaces.

16. The method of claim 14, wherein, prior to forming the dielectric layer, the method comprises forming a metal layer in the interstitial spaces on the exposed first surface of the multi-layer substrate and lateral surfaces of the fingers of the first and second sets of fingers.

17. The method of claim 16, wherein the metal layer comprises a counter electrode metal.

18. The method of claim 14, wherein the dielectric layer comprises a tantalum oxide or a material having a relative dielectric permittivity greater than approximately fifty.

19. The method of claim 14, wherein the first and second set of fingers extend from the first surface of the multi-layer substrate.

20. The method of claim 14, wherein sidewall surfaces of the first and second set of fingers are orthogonal to the first surface of the multi-layer substrate.

21. The method of claim 14, wherein the dielectric layer extends from the first surface of the multi-layer substrate and covers the first and second set of fingers.

22. A packaged integrated circuit (IC), comprising:
a multi-layer substrate having first and second opposing surfaces;
a capacitor on the second surface of the multi-layer substrate, the capacitor comprising:
first and second sets of interdigitated and electrically conductive fingers extending from a first surface of a substrate layer to terminate at a second surface of the substrate layer, wherein the first and second sets of fingers extend orthogonally to the second surface of the multi-layer substrate to define interstitial spaces between adjacent pairs of fingers of the first and second sets of fingers, and the second surface of the multi-layer substrate is exposed in the interstitial spaces between the adjacent pairs of fingers; and
a dielectric layer disposed in the interstitial spaces between the adjacent pairs of fingers;
active circuitry in the multi-layer substrate or in at least one other layer on the first surface of the multi-layer substrate; and
a molding compound encapsulating the active circuitry, the multi-layer substrate, and the capacitor.

23. The packaged IC of claim 22, further comprising first and second terminals coupled to the first and second sets of fingers, respectively, wherein the active circuitry is coupled to the first and second terminals.

24. The packaged IC of claim 23, wherein the active circuitry is non-coplanar with the capacitor.

25. The packaged IC of claim 22, comprising a metal layer in the interstitial spaces on the exposed first surface of the multi-layer substrate and on lateral surfaces of the fingers of the first and second sets of fingers.

26. The packaged IC of claim 22, wherein the dielectric layer comprises tantalum oxide or a material having a relative dielectric permittivity greater than approximately fifty.

27. A packaged integrated circuit (IC), comprising:
a multi-layer substrate having first and second opposing surfaces;
a capacitor on the second surface of the multi-layer substrate, the capacitor comprising:
first and second sets of interdigitated and electrically conductive fingers extending from a first surface of a substrate layer to terminate at a second surface of the substrate layer, wherein the first and second sets of fingers extend orthogonally to the second surface of the multi-layer substrate to define interstitial spaces between adjacent pairs of fingers of the first and second sets of fingers, and the second surface of the multi-layer substrate is exposed in the interstitial spaces between the adjacent pairs of fingers; and
a dielectric layer disposed in the interstitial spaces between the adjacent pairs of fingers; and
a molding compound encapsulating the substrate layer, the multi-layer substrate, and the capacitor.

28. The packaged IC of claim 27, further comprising an active circuit in the multi-layer substrate or in at least one other layer on the first surface of the multi-layer substrate.
